(19) United States
(12) Patent Application Publication
(10) Pub. No.: US 2023/0360927 A1
(43) Pub. Date: Nov. 9, 2023

(54) METHOD OF MANUFACTURING SEMICONDUCTOR DEVICES, CORRESPONDING DEVICE AND SYSTEM

(71) Applicant: STMicroelectronics S.r.l., Agrate Brianza (MB) (IT)

(72) Inventor: Fulvio Vittorio FONTANA, Monza (IT)

(73) Assignee: STMicroelectronics S.r.l., Agrate Brianza (MB) (IT)

(21) Appl. No.: 18/140,375

(22) Filed: Apr. 27, 2023

(30) Foreign Application Priority Data
May 3, 2022 (IT) 102022000008903

(51) Int. Cl. H01L 21/48; H01L 21/56; H01L 21/033; H01L 23/31; H01L 23/495

(52) U.S. Cl. CPC H01L 21/4828; H01L 21/565; H01L 21/0335; H01L 21/0332; H01L 23/3171; H01L 23/4951

(57) ABSTRACT

A semiconductor integrated circuit chip is arranged on a first surface of a substrate that includes electrically conductive lead formations in an array, wherein the electrically conductive lead formations are covered by a masking layer at a second surface opposite the first surface. The semiconductor integrated circuit chip is electrically coupled to electrically conductive lead formations and an insulating encapsulation is molded on the semiconductor integrated circuit chip. The masking layer is then selectively removed, for example, via laser ablation, from one or more of the electrically conductive lead formations. The electrically conductive lead formations that are left uncovered by the masking layer are then removed by an etching process applied to the second surface of the substrate. The selective removal of the unmasked electrically conductive lead formations serves to increase a creepage distance between those conductive lead formations that are left in place.

### PRIORITY CLAIM

This application claims the priority benefit of Italian Application for Patent No. 102022000008903 filed on May 3, 2022, the content of which is hereby incorporated by reference in its entirety to the maximum extent allowable by law.

### TECHNICAL FIELD

The description relates to semiconductor devices.

One or more embodiments can be applied to semiconductor devices such as integrated circuits (ICs), for instance.

### BACKGROUND

In certain applications such as automotive applications, a satisfactory creepage distance between solder joints connected to battery and ground is a desirable feature for electrical modules assembled on a printed circuit board (PCB).

A satisfactory creepage distance facilitates avoiding short circuits (briefly, shorts) which may cause faulty operation, even fires on cars. Shorts can be related, for instance to surface mount technology (SMT) assembly processes, for instance, due to flux residuals leading to copper migration or to conductive contaminants possibly left over on final products.

Creepage distance is a common designation for the shortest distance between two conductive parts over an insulating material. The value of that distance may be a function of an application voltage and can be defined in specifications such as, for instance, JEDEC memory standards for semiconductor memory circuits and similar storage devices (see jedec.org), standards such as DIN EN 60664 and/or in automotive customer specifications.

An approach to address issues related to creepage distance may involve removing contact leads from a full lead lay-out for a semiconductor device, thus increasing the spacing between critical contact leads connected to battery and ground.

A drawback of such an approach lies in that it involves customizing the leadframe and/or the substrate layout according to the associated pin list. This results in additional costs and lead-time issues.

Another approach, as discussed in Italian Patent No. 102020000012910 (incorporated herein by reference), involves arranging at least one semiconductor chip on a substrate comprising an array of electrically conductive leads and electrically coupling the semiconductor chip to electrically conductive leads in the array. An electrically insulating encapsulation of the semiconductor chip arranged on the substrate is provided leaving the electrically conductive leads exposed at a surface of the encapsulation. Electrically insulating material such as solder resist material is then provided (for example, via jet printing, aerosol printing, mesh printing or oxide growth) on selected ones of the electrically conductive leads exposed at the surface of the encapsulation.

While providing satisfactory results, such an approach may still be exposed to the risk that the electrically insulating material may be sensitive to scratches generated during handling and assembly steps.

There is a need in the art to contribute in providing improved solutions overcoming the drawbacks discussed in the foregoing.

### SUMMARY

One or more embodiments may relate to a method.

One or more embodiments may relate to a corresponding device.

One or more embodiments may relate to a corresponding system. One or more semiconductor devices arranged on a printed circuit board, PCB may be exemplary of such a system.

In a method as described herein, one or more semiconductor integrated circuit chips are arranged on a first surface of a substrate comprising electrically conductive formations such as an array of electrically conductive leads covered by a masking layer at a second surface, opposite the first surface. The semiconductor chip or chips are coupled to electrically conductive leads in the array and an insulating encapsulation is molded on the semiconductor chip or chips arranged on the first surface of the substrate. The masking layer is selectively removed, for example, via laser ablation, from one or more of the electrically conductive leads (or other electrically conductive formations) that are thus left uncovered by the masking layer. Etching is applied to the second surface of the substrate so that the electrically conductive formations such as leads left uncovered by the masking layer are removed, thus increasing the creepage distance to other electrically conductive formations that are left in place.

One or more embodiments provide a solution to customize a standard pre-plated leadframe (for example, a full array JEDEC Quad Flat No-lead (QFN) leadframe).

After package molding and before back etching, the plating (for example, few tens of nanometers of NiPdAu) is ablated with a laser at the location of the lead or leads to be removed, exposing the metal, for example, copper, from the bulk of the substrate (leadframe). Then, during back etching, exposed (that is, unmasked) leads are etched away at the same time the other (masked) leads are “set free”.

Solutions as discussed herein thus involve encapsulation molding followed by selective removal (for example, by laser ablation) of a masking layer (for example, a pre-plating NiPdAu layer) provided at lead locations to expose the substrate metal (for example, copper). Back-etching as applied to free the (masked) leads removes the exposed (unmasked) leads, thus increasing creepage distance as desired.

The resulting device will exhibit, at the locations where the exposed (unmasked) leads are removed, recessed portions (“dimples”) in the encapsulation that are easily detectable by naked-eye or optical microscope inspection. Also, laser machining used to selectively remove the masking layer (for example, a pre-plating NiPdAu layer) may leave a trace in the molding compound of the encapsulation.

### BRIEF DESCRIPTION OF THE DRAWINGS

One or more embodiments will now be described, by way of example only, with reference to the annexed figures, wherein:

FIG. 1 is a partial view of a semiconductor device exemplary of a creepage distance therein;

FIG. 2 is a complete view of a semiconductor device suited to be processed as discussed herein;

FIG. 3 is a complete view of a semiconductor device that has been processed as discussed herein;

FIG. 4 is a flow chart exemplary of a sequence of steps as discussed herein;

FIGS. 5 and 6 are partial perspective views of a semiconductor device illustrating certain steps of the sequence of FIG. 4;

FIGS. 7A, 7B, 7C and 7D are partial cross-sectional views of a semiconductor device being processed as discussed herein; and

FIG. 8 is a schematic representation of a system including semiconductor devices as described herein.

### DETAILED DESCRIPTION

The figures are drawn to clearly illustrate the relevant aspects of the embodiments and are not necessarily drawn to scale.

Corresponding numerals and symbols in the different figures generally refer to corresponding parts unless otherwise indicated.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular conformations, structures, or characteristics may be combined in any adequate way in one or more embodiments.

The headings/references used herein are provided merely for convenience and hence do not define the extent of protection or the scope of the embodiments.

Also, throughout the figures, like parts or elements are indicated with like reference symbols, and a corresponding description will not be repeated for each and every figure for brevity.

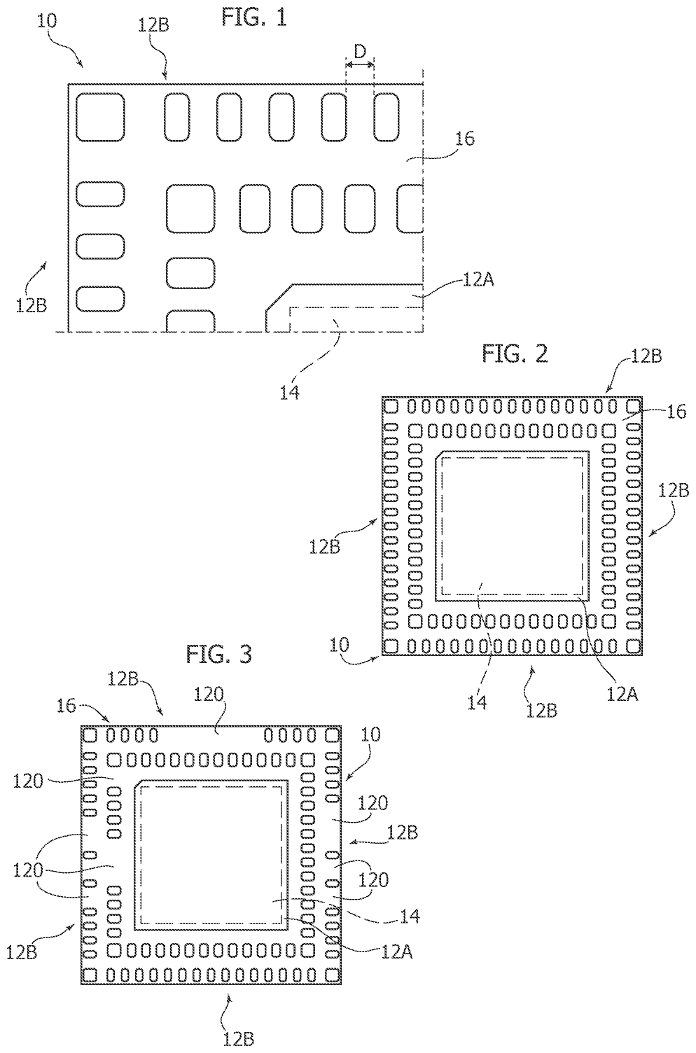

FIG. 1 is a partial (rear or bottom) view of a semiconductor device 10 of the Quad Flat No-lead (QFN) type.

This type of device is just exemplary of a variety of semiconductor devices where a creepage distance having (at least) a certain minimum value D between electrically conductive formation such as leads represents a feature to pursue. Consequently, the embodiments are not limited to the possible use in QFN semiconductor devices.

As conventional in the art, a device 10 as exemplified herein may comprise a substrate such as a so-called lead frame (or leadframe) including a die pad 12A and an array of electrically conductive leads 12B around the die pad 12A.

The leads 12B are configured to provide electrical contact according to a desired routing pattern for one or more semiconductor integrated circuit chips or dice 14 arranged on a die arranging area of the die pad 12A.

Part of the outline of such a chip or die 14 (only one is considered here for simplicity) is illustrated in dashed lines in FIGS. 1 to 3.

The designation lead frame (or leadframe) is currently used (see, for instance the USPC Consolidated Glossary of the United States Patent and Trademark Office) to indicate a metal frame which provides support (here at 12A) for a semiconductor chip or die (here 14) as well as electrical leads (here 12B) to couple the semiconductor chip or die to other electrical components or contacts.

Essentially, a leadframe comprises an array of electrically conductive formations (such as the leads 12B) which from a peripheral location extend inwardly in the direction of the semiconductor chip or die 14, thus forming an array of electrically conductive formations from the die pad 12A configured to have at least one semiconductor chip or die attached thereon. This may be via a die attach adhesive (a die attach film (DAF), for instance).

It is noted that the indication “No-leads” referred to a QFN device as depicted herein is not in contradiction with such a package comprising an array of leads such as 12B: in fact, the indication “No-leads” is related to the fact that a QFN package is substantially exempt from external (distal) tips of the leads in the leadframe 12 projecting radially outwardly of the package.

In a conventional arrangement as exemplified in FIG. 2, a packaged semiconductor device 10 includes: a metal leadframe 12A, 12B; at least one semiconductor chip or die 14 attached onto a die pad 12A in the leadframe; bond wires or like electrically conductive formations (not visible in the figure) that electrically connect bonding pads on the chip or die 14 to individual leads 12B of the leadframe; and hard insulating encapsulant material 16 (for instance, a molding compound plastic resin such as an epoxy resin) that covers the other components and forms the exterior of the package.

The leadframe 12A, 12B provides the supporting structure for the placement of the semiconductor die or dice 14, in particular during assembly of the packaged device, and external contactors.

As noted, the foregoing is conventional in the art, which makes it unnecessary to provide a more detailed description herein.

FIG. 1 is exemplary of the possible existence, in a semiconductor device such as the device 10, of a creepage distance D, namely a shortest distance between two conductive parts (here two leads 12B) over an insulating material such as the encapsulant package material 16.

FIG. 2 is exemplary of a semiconductor device 10, wherein a creepage distance (see the distance D in FIG. 1) is desired to be formed between two conductive parts such as leads 12B. To that effect one or more leads 12B should desirably be “removed” at one or more locations such as the locations indicated by way of example by the references 120 in FIG. 3.

As discussed, a satisfactory creepage distance is a desirable feature in order to avoid short circuits (shorts): it will be otherwise appreciated that, while a creepage distance between leads 12B is primarily referred to herein for simplicity, the same criteria apply to providing a desired creepage distance between electrically conductive formations at least one of which is not a lead.

As discussed, an approach to address this issue would involve removing this or these “undesired” contact leads from a full lead lay-out for a semiconductor device (see FIG. 2) by customizing that substrate layout according to an associated pin list.

This would result in undesirable additional costs and lead-time issues.

Another possible approach, as discussed in Italian Patent No. 102020000012910 (already cited above) involves coating the undesired leads with electrically insulating material such as solder resist. As noted, such an electrically insulating material may be sensitive to scratches generated during handling and assembly steps, which can be regarded as a drawback.

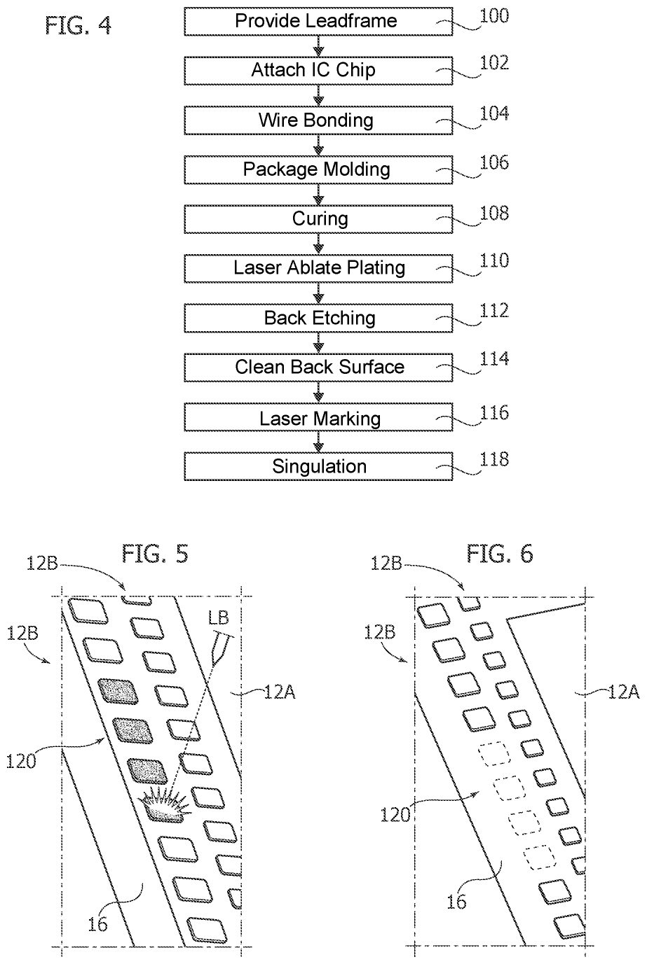

The flow chart of FIG. 4 is exemplary of possible steps or actions involved in manufacturing a semiconductor device such as the device 10 by adequately addressing these issues.

Those of skill in the art will otherwise appreciate that a manufacturing method as exemplified herein may include various additional (sub)steps which are not visible in FIG. 4 for simplicity and/or variations of the steps described, for example, as a function of the technologies involved and/or specific features of the products manufactured. Also, while advantageous, the whole exact sequence of steps illustrated in FIG. 4 is not mandatory for the embodiments.

As exemplified in FIG. 4, a manufacturing method as considered herein comprises—as exemplified in block 100—providing a substrate (a metal leadframe 12A, 12B, for instance). This may be in the form of a continuous strip used for manufacturing plural devices to be finally separated or “singulated” as exemplified by block 118 discussed in the following.

Also, it will be assumed that the leadframe 12A, 12B is of a pre-plated type (pre-plated frame (PPF) as conventional in full array JEDEC QFNs) that is with a plating of NiPdAu (nickel, palladium and gold) or the like, applied on the back or bottom surface.

The back or bottom surface is the surface opposed to the front or top surface onto which the semiconductor chip or chips 14 are mounted. The plating is provided (in a manner known per se to those of skill in the art) at least at those locations where conductive leads 12B (or other electrically conductive formations) may be intended to be provided.

The wording “may” takes into account the fact that a solution as described herein is intended to facilitate ultimately providing leads 12B only at certain ones of these locations, while one or more “undesired” leads can be selectively “removed”.

Block 102 in FIG. 4 is exemplary of attaching on the front or top surface of the leadframe (at the die pad 12A, for instance) at least one semiconductor chip or die (for example, 14).

This is followed (in block 104) by providing a wire bonding pattern (or the like) that electrically connects bonding pads on the chip or die 14 to individual leads (for example, 12B) of the leadframe.

Block 106 is exemplary of molding an insulating package material 16 (for example, epoxy resin) onto the assembly thus formed, and block 108 is exemplary of post mold curing of the encapsulation formed by the insulating package material 16 thus molded.

To summarize, the steps or actions 100 to 108 are exemplary of arranging at least one semiconductor chip 14 on a first surface of a substrate (die pad 12A plus leads 12B).

The substrate comprises an array of electrically conductive formations (for example, leads 12B) that are covered by a masking layer 1200 (for example, NiPdAu) at a second surface opposite the first surface.

The semiconductor chip or chips 14 are electrically coupled (for example, via a wire bonding pattern, not visible for simplicity) to selected ones of the leads 12B in the array of electrically conductive leads.

An insulating encapsulation 16 (for example, an epoxy resin) is molded on the semiconductor chip or chips 14 arranged on the first surface of the substrate (leadframe) 12A, 12B,

The steps or actions 100 to 108 are otherwise conventional in the art, which makes it unnecessary to provide a more detailed description herein.

The block 110 in FIG. 4 is exemplary of a step where, as represented in FIG. 5, laser beam energy LB is applied to remove (laser ablate) the (for example, NiPdAu) plating layer at that location or those locations 120 where electrically conductive formations such as the leads 12B are desired to be removed.

The block 112 in FIG. 4 is exemplary of back etching (for example, chemical or plasma etching) where the metal material (for example, copper) of the leadframe is etched away (again in a manner known per se to those of skill in the art) in order to “free” the leads 12B at those locations of the leadframe material that are covered by the (for example, NiPdAu) plating.

Conversely, those regions or areas of the leadframe material (for example, copper) that are left exposed by the plating 1200 removed via laser ablation are etched away, for example, via chemical or plasma etching as conventional in the art) as illustrated in FIG. 6: the figure shows that the leads located at the areas 120 are removed, thus increasing the (creepage) distance between neighboring leads 12B.

It is noted that, even in a “customized” device 10 as exemplified in FIG. 3, the wire bonding pattern formed in step 104 may be the same wire bonding pattern provided in a “standard” device as exemplified in FIG. 2, so that the solution described herein will have a reduced impact on the whole assembly flow.

Blocks 114, 116 and 118 are exemplary of steps where the etched back surface is cleaned (via water jet or plasma cleaning) in order to improve lead wettability, with subsequent laser marking and final singulation to provide individual devices 10.

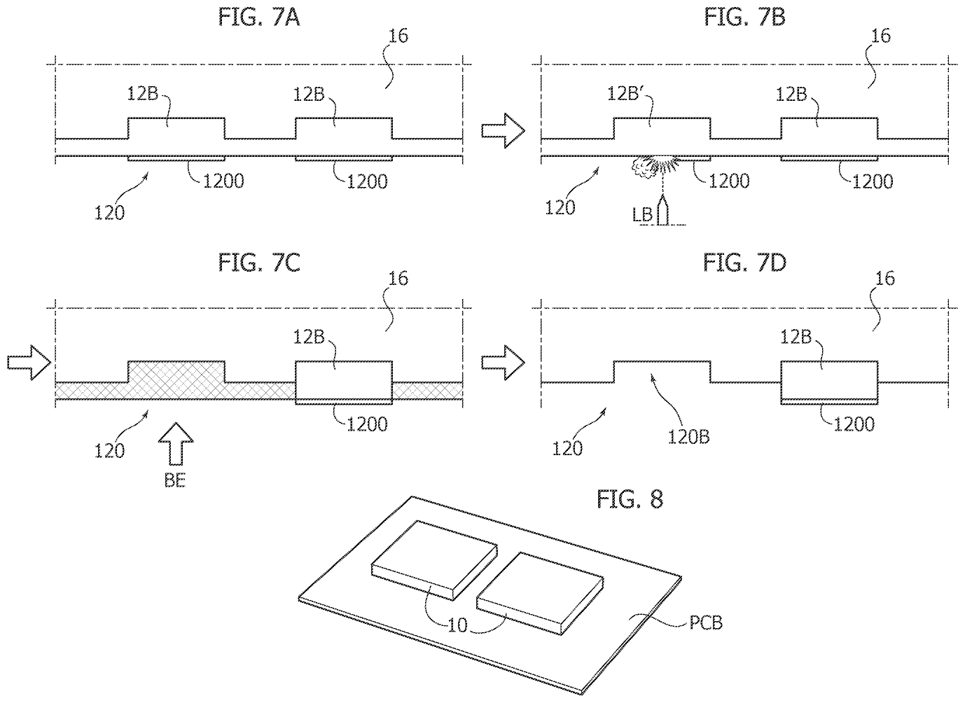

The effects of selective laser ablation in step 110 and back etching in step 122 are further exemplified in FIGS. 7A to 7D.

FIG. 7A shows the leadframe material (at the bottom of the figure) having a masking layer 1200 (for example, NiPdAu plating) selectively provided at those locations where leads (or other electrically conductive formations) 12B are intended to be provided in a standard full lead lay-out for a semiconductor device as exemplified in FIG. 2.

FIG. 7B shows the plating 1200 selectively removed via laser beam LB in those areas or regions 120 where leads 12B′ are intended to be removed in a customized lead lay-out as exemplified in FIG. 3, for example, to facilitate achieving desired creepage performance.

FIG. 7C shows back etching BE being applied (block 112 in FIG. 4).

FIG. 7D shows that, as a result of back etching BE, those regions or areas of the leadframe material (for example, copper) that are unmasked (that is are left exposed by the masking layer 1200), including those where the plating 1200 was removed via laser ablation, are etched away.

The lead or leads 12B′ located at the areas 120 are thus removed increasing the (creepage) distance between non-etched neighboring leads 12B that remain in place as desired thus providing a customized lead lay-out as exemplified in FIG. 3. The insulated distance between these neighboring leads can thus be appreciably increased, which may result is a notable improvement in terms of creepage distance.

As visible in FIG. 7D, recessed/depressed areas (“dimples”) 120B in the encapsulation 16 remain as “testimonials” of the leads 12B′ that were removed.

FIGS. 7A to 7B (where the semiconductor die or dice 14 and the associated wire bonding are not illustrated for simplicity) are thus exemplary of the masking layer 1200 being removed from at least one of the leads, namely the lead indicated by 12B′ in the array electrically conductive leads 12B in the leadframe.

The lead or leads 12B′ (or other electrically conductive formations) are thus left uncovered by the masking layer 1200 so that, when applying (back) etching to the second (back) surface of the substrate this or these leads 12B′ or formations left uncovered by the (laser ablated) masking layer 1200 are removed, advantageously leaving recessed portions 120B in the encapsulation.

These recessed portions 120B further increase the (creepage) distance between non-etched neighboring leads by providing a longer (developed) distance over the surface of the encapsulation between non-etched neighboring leads, compared to the situation where some leads would be absent from leadframe by design.

Devices 10 as resulting from singulation (block 118 in FIG. 4) can be arranged onto a support substrate such as a printed circuit board, PCB via a pick-and-place tool to provide a system as exemplified in FIG. 8.

FIG. 8 is exemplary of arranging one or more devices 10 (for example, QFN multi-row packages) on a support substrate such as a printed circuit board, PCB to provide a system with improved creepage distance.

Such a system can be advantageously used in order to counter undesired “short” events. This may be the case in the automotive sector, for instance, where such events may have serious consequences.

Without prejudice to the underlying principles, the details and the embodiments may vary, even significantly, with respect to what has been described by way of example only without departing from the scope of the embodiments.

The claims are an integral part of the technical disclosure provided herein in connection with the embodiments.

The extent of protection is determined by the annexed claims.

1. A method, comprising steps performed in the following order:
arranging a semiconductor integrated circuit chip on a first surface of a substrate, the substrate comprising electrically conductive lead formations covered by a masking layer at a second surface opposite the first surface;
providing an insulating encapsulation of the semiconductor integrated circuit chip arranged on the first surface of the substrate;
removing the masking layer that covers at least one of the electrically conductive lead formations between first and second ones of the electrically conductive lead formations covered by the masking layer in order to leave said at least one of the electrically conductive lead formations uncovered by the masking layer; and
applying etching to the second surface of the substrate to remove said at least one of the electrically conductive lead formations that was left uncovered by removal of the masking layer in order to control a creepage distance between said first and second ones of the electrically conductive lead formations.

2. The method of claim 1, wherein removing the masking layer comprises laser ablating said masking layer from said at least one of the electrically conductive formations at the second surface of the substrate.

3. The method of claim 2, wherein the masking layer is a NiPdAu layer.

4. The method of claim 1, wherein the substrate comprises at least one semiconductor integrated circuit chip mounting area at the first surface of the substrate and the electrically conductive lead formations comprise an array of electrically conductive leads around the said semiconductor chip mounting area, and wherein arranging the semiconductor integrated circuit chip comprises mounting the semiconductor integrated circuit chip to the at least one semiconductor integrated circuit chip mounting area.

5. A semiconductor device, comprising:
a semiconductor integrated circuit chip arranged on a first surface of a substrate, the substrate comprising electrically conductive leads at a second surface opposite the first surface, the electrically conductive leads at the second surface of the substrate being covered by a masking layer;
an insulating encapsulation that encapsulates the semiconductor integrated circuit chip arranged on the first surface of the substrate; and
at least one recessed portion of the insulating encapsulation, wherein the recessed portion is located between first and second ones of the electrically conductive leads covered by the masking layer in order to provide a desired creepage distance between the first and second ones of the electrically conductive leads.

6. The device of claim 5, wherein the masking layer is a NiPdAu layer.

7. The device of claim 5, wherein the semiconductor integrated circuit chip is arranged at a semiconductor integrated circuit chip mounting area at the first surface of the substrate and the electrically conductive leads are arranged in an array around the semiconductor integrated circuit chip mounting area.

8. A system, comprising:
a support board;
a semiconductor device placed on said support board;
wherein said semiconductor device comprises:
a semiconductor integrated circuit chip arranged on a first surface of a substrate, the substrate comprising electrically conductive lead formations at a second surface opposite the first surface, the electrically conductive lead formations at the second surface of the substrate being covered by a masking layer;
an insulating encapsulation that encapsulates the semiconductor integrated circuit chip arranged on the first surface of the substrate; and
at least one recessed portion of the insulating encapsulation, wherein the recessed portion is located between first and second ones of the electrically conductive leads covered by the masking layer in order to provide a desired creepage distance between the first and second ones of the electrically conductive leads;
wherein the electrically conductive lead formations are electrically connected to the support board.
